(19) United States
(12) Patent Application Publication
(10) Pub. No.: US 2025/0201529 A1
(43) Pub. Date: Jun. 19, 2025

(54) COATINGS ON INNER SURFACES OF PARTICLE CONTAINMENT CHAMBERS

(71) Applicant: Helion Energy, Inc., Everett, WA (US)

(72) Inventors: Brian Campbell, Shoreline, WA (US); Sachin Desai, Everett, WA (US); David Kirtley, Seattle, WA (US); Anthony Pancotti, Kenmore, WA (US); Christopher James Pihl, Woodinville, WA (US)

(73) Assignee: Helion Energy, Inc., Everett, WA (US)

(21) Appl. No.: 18/838,936

(22) PCT Filed: Feb. 16, 2023
(86) PCT No.: PCT/US2023/062745

§ 371 Date: Aug. 15, 2024

Related U.S. Application Data
(60) Provisional application No. 63/310,793, filed on Feb. 16, 2022.

(51) Int. Cl. H01J 37/32; C23C 16/27; C23C 16/34

(52) U.S. Cl. CPC H01J 37/32486; C23C 16/276; C23C 16/342; H01J 37/32504; H01J 37/32669

(57) ABSTRACT

Thermally conductive coatings are deposited on an inner surface of a particle containment chamber to mitigate excessive heating of the inner surface. A particle manipulation system includes a particle containment plasma containment chamber with a thermally-conductive coating comprising bort, graphite, and/or diamond on the inner surface of the chamber. The coating material and thickness can be selected to absorb a majority of energetic radiation (such as X-rays) incident on the coating and transport heat generated by the absorbed X-rays away from the inner surface of the chamber. Methods of deposition, including in situ deposition, are also described.

### CROSS-REFERENCE TO RELATED APPLICATIONS

The present application claims a priority benefit, under 35 U.S.C. § 119 (e), to U.S. provisional application Ser. No. 63/310,793 filed on Feb. 16, 2022, titled “Bort Coatings on Inner Surfaces of Plasma Confinement Chambers,” which application is incorporated herein by reference in its entirety.

### BACKGROUND

Electrons with keV energies (e.g., 1 keV to 10 keV) can emit Bremsstrahlung radiation in the form of high-energy X-rays when, for example, interacting with other charged particles, such as atomic nuclei. Such high energy X-ray emissions can also come from activation decay, synchrotron radiation, cyclotron radiation, and beta decay. Further, electron excitation during ionization or recombination may also generate high energy photons, such as X-rays.

Plasma containment chambers can be used for the generation of high-energy particles, and may also be used to accelerate particles or objects to high velocities. High-energy particles, such as high-energy electrons and ions, can generate significant electromagnetic radiation when interacting with other charged particles, and also when interacting with a magnetic field (e.g., in a Bremsstrahlung process). Intense magnetic or electric fields may be used to confine and accelerate the high-energy particles and/or plasma. The electromagnetic radiation produced and the high-energy particles can heat and/or degrade wall surfaces of the plasma containment chamber in some cases to the point where the wall surfaces must be replaced for proper operation of the system.

### SUMMARY

The described technology relates to particle manipulation systems and particle containment chambers, an example of which is a plasma containment chamber. A particle manipulation system can move, accelerate, decelerate particles such as electrons, ions, and/or atoms of a plasma. A particle containment chamber can be configured to contain high-energy particles, such as accelerated electron, ions, and atoms of a plasma, that can produce energetic radiation, such as X-rays and/or gamma rays. In some cases, energetic atoms in the plasma can undergo fusion releasing gamma rays and high energy particles that can result in the production of X-rays. The radiation can be absorbed by a coating on an inner surface of the particle containment chamber that mitigates excessive and potentially damaging heating of the inner surface of the chamber that would otherwise occur without the coating.

Some implementations relate to a method of containing a plasma in a plasma chamber. The method can include acts of: injecting a plasma into the plasma chamber; applying a magnetic field to the plasma to manipulate the plasma; receiving, in a coating deposited on an inner surface of a wall of the plasma chamber that faces the plasma, electromagnetic radiation including X-rays from the plasma, a portion of the X-rays having a range of energies, wherein a thickness of the coating is at least one-half a penetration depth for the portion of the X-rays having the range of energies and for which at least 50% of the X-rays having the range of energies are absorbed within 1 millimeter of the inner surface of the wall without the coating present.

Some implementations relate to a plasma chamber to contain a plasma. The plasma chamber can include: a wall surrounding a volume in which the plasma is contained when the plasma chamber is in operation and a coating in thermal communication with an inner surface of the wall to receive electromagnetic radiation including X-rays from the volume. A portion of the X-rays can have a range of energies. A first thermal conductivity of the coating can be greater than a second thermal conductivity of the wall of the plasma chamber. A thickness of the coating can be at least one-half a penetration depth for X-rays in the range of energies, and at least 50% of the X-rays having the range of energies are absorbed within 1 millimeter of the inner surface of the wall without the coating present.

Some implementations relate to a system comprising: a plasma chamber having a wall extending around an inner volume, the plasma chamber adapted to support a vacuum in the inner volume, the wall of the plasma chamber having a thermal conductivity no greater than 5 W m⁻¹ K⁻¹; a plasma source to generate a plasma and to inject the plasma into the inner volume of the plasma chamber; at least one gas inlet coupled to the plasma source, to introduce a gas or a gaseous mixture into the plasma source; and a plurality of electromagnetic coils arranged to generate a magnetic field within the plasma chamber, such that interaction of particles of the plasma with the magnetic field generates electromagnetic radiation including X-rays. A first portion of the X-rays are absorbable by the wall of the plasma chamber to cause heating of the wall. The plasma chamber can further include a coating comprising at least one of bort, boron nitride, graphite, or diamond, wherein the coating is disposed on an inner surface of the wall of the plasma chamber to absorb at least a second portion of the X-rays included in the first portion of the X-rays, such that localized peak heating of the wall near the inner surface that occurs during operation of the system due to absorption of the first portion of the X-rays is reduced compared to absorption that would occur of the first portion of the X-rays without having the coating present.

Some implementations relate to a method of depositing a coating on an inner surface of a wall of a plasma chamber for which electromagnetic radiation including X-rays will be incident on the coating, wherein a portion of the X-rays have a range of energies. The method can include acts of: heating the plasma chamber such that the inner surface of the wall is at a temperature from 300° C. to 2500° C.; and introducing a gas mixture into the plasma chamber. The gas mixture can include: a first gas comprising a hydrocarbon; and a second gas comprising at least one of protium or deuterium. The method can further include acts of generating a plasma in the plasma chamber; and depositing the coating on the inner surface of the wall. The coating can include at least one of diamond, graphite, or bort. The coating can be deposited to a thickness of at least one-half a penetration depth for the portion of X-rays having the range of energies. At least 50% of the X-rays having the range of energies are absorbed within 1 millimeter of the inner surface of the wall without the coating present.

Some implementations relate to a method of refreshing a coating on an inner surface of a plasma confinement system. The plasma confinement system can comprise: a plasma chamber having a bort coating on at least a portion of an inner surface of the plasma chamber, wherein the bort coating is arranged to receive, from a plasma confined by the plasma confinement system, X-rays having a range of energies. The method can include acts of: purging the plasma chamber to remove any residual gasses; heating the inner surface of the plasma chamber to a temperature in a range from 300° C. to about 2500° C.; and introducing a gas mixture into the plasma chamber. The gas mixture can include: a first gas comprising a hydrocarbon; and a second gas comprising at least one of protium or deuterium. The method can further include acts of: generating a plasma in the plasma chamber by applying a radio-frequency electromagnetic wave to dissociate and ionize the gas mixture; and depositing additional bort on the bort coating to refresh the bort coating on the inner surface of the plasma chamber such that the refreshed bort coating absorbs at least half of the X-rays having the range of energies.

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally and/or structurally similar elements).

FIG. 1A illustrates an example of a particle manipulation system having a plasma containment chamber.

FIG. 1B depicts a portion of the tubular chamber of FIG. 1A having a coating applied to the inner surface of the chamber wall.

FIG. 2A illustrates X-ray penetration depth in quartz and diamond.

FIG. 2B depicts an example energy spectrum for X-rays having a range of energies.

FIG. 3 illustrates a diamond or bort deposition scheme.

FIG. 4 illustrates a particle manipulation system configured for in situ deposition of a coating on an inner surface of the containment chamber.

FIG. 5 illustrates a cross-section of a plasma containment chamber with a bort coating.

FIG. 6A illustrates a cross-section of a plasma containment chamber having channels through the chamber wall.

FIG. 6B illustrates a cross-section of a plasma containment chamber having the chamber wall formed in sections.

FIG. 7A illustrates a cross-section of a plasma containment chamber having a multilayer coating.

FIG. 7B illustrates a cross-section of a portion of a wall of a plasma containment chamber having a multilayer coating.

### DETAILED DESCRIPTION

### 1. Plasma Confinement and Thermal Management

Plasma confinement is the restriction of the spatial extent of a plasma in at least one dimension within a vacuum environment, where the confinement is typically achieved by applying electric and/or magnetic fields to the vacuum environment. A plasma can be confined and manipulated (e.g., translated, accelerated, decelerated, compressed, and expanded, to change its density and energy. Compression can be used to heat a plasma to very high temperatures (e.g., over a hundred million degrees or more) by adding energy to the plasma, reducing the available volume and increasing the probability of collisions between particles in the plasma. This in turn can promote ionization of particles of the plasma, such that it can increase ion lifetimes in the plasma. Plasma confinement and manipulation are useful for a variety of research and manufacturing applications including, but not limited to, plasma reactions (e.g., chemical or atomic reactions), particle and object acceleration systems (e.g., for fundamental research or generation of industrial or medical isotopes), and material deposition (e.g., chemical vapor deposition).

Particle manipulation systems may use intense magnetic fields (e.g., peak field values between 0.01 Tesla (T) and 50 T) to confine and (if desired) increase the kinetic energy of the particles. Intense magnetic fields can be generated by multiple magnetic coils that are arranged around a particle containment chamber to cooperatively produce a magnetic field within the chamber. As an example, the chamber may be a tube, a torus, a sphere, or box. To cooperatively produce a magnetic field, the magnetic coils are spaced near enough so that the magnetic field produced by any one coil adds to the magnetic field produced by at least one other coil in the system.

Alternatively, or in addition to using magnetic fields, particle manipulation systems may use electric fields to confine and/or manipulate the particles (e.g., increase the kinetic energy of the plasma or particles). For example, inertial confinement systems use electric fields to confine a plasma instead of using magnetic fields for confinement. Many inertial electrostatic confinement systems pull electrons or ions across a potential well, beyond which the potential drops and the particles continue to move due to their inertia. To create the potential well, an inertial electrostatic confinement system may include an arrangement of conductive wire grids (e.g., two concentric metal wire spherical grids). These confinement systems may also use electron guns instead of, or in addition to, electric grids. Examples of systems that use electric fields to confine or increase the kinetic energy of plasma or particles include some ion engines (also called thrusters), vacuum tubes, electron guns, and accelerators that use alternating electric fields.

In other cases, some particle manipulation systems combine magnetic and electric fields to confine and/or manipulate particles. Examples of such systems include the polywell and the Penning trap. Lasers, neutral beam injection, and/or directed radio frequencies (known as RF heating) can also be used with any of the above systems to accelerate charged particles to high energy states in a plasma confined with magnetic or electric fields. In any of these systems, the chamber containing the vacuum with the plasma may still be a tube, torus, sphere, box, or other arrangement.

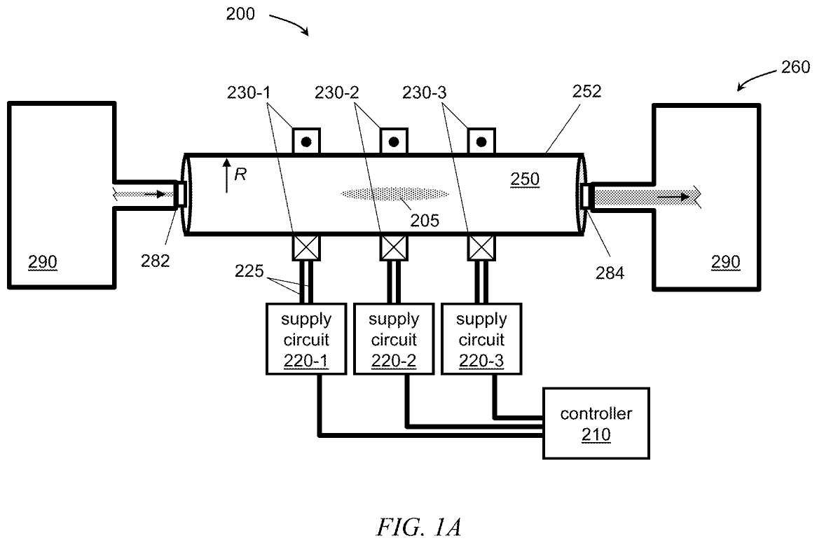

FIG. 1A depicts an example of a particle manipulation system 200 configured to confine and manipulate a plasma 205. The system 200 includes a tubular chamber 250 in which the plasma 205 is confined by a magnetic field. The system 200 further includes electromagnetic coils 230-1, 230-2, 230-3 (referenced together as 230) surrounding the tubular chamber 250 to generate the magnetic field within the chamber 250. The system can further include electronic circuitry (e.g., supply circuits 220) and a controller 210 to drive electric currents through the coils 230, thereby generating the magnetic field within the tubular chamber 250. Additional details of an example particle manipulation system 200 are described in international application PCT/US2022/032276, titled “Apparatus and Methods for Generating a Pulsating, High-Strength Magnetic Field,” filed Jun. 3, 2022, which application is incorporated herein by reference in its entirety.

Plasma confinement using magnetic fields can benefit from chamber walls 252 formed from a dielectric and/or non-magnetic material that does not interfere with the magnetic fields that pass through the chamber walls 252 to confine the plasma 205. The dielectric and/or non-magnetic material may also have certain other desirable features for use in plasma environments such as vacuum compatibility, resistance to sputtering, and/or mechanical durability. Currently, cost-effective materials that are dielectric and have these features (such as some ceramics, silica, and graphite) have low thermal conductivity (e.g., less than 5 watts per meter per Kelvin (W m⁻¹ K⁻¹) and therefore cannot readily dissipate heat that can be generated within the tubular chamber 250. For example, the chamber walls 252 may be formed from a material having a thermal conductivity no greater than 5 W m⁻¹ K⁻¹, no greater than 3 W m⁻¹ K⁻¹, or even in some cases no greater than 1.5 W m⁻¹ K⁻¹.

The tubular chamber 250, in which at least one plasma 205 is contained during operation of the system 200, may have one or two open ends or openings (e.g., for the injection and removal of the plasma). The tubular chamber 250 can have one or more cross-sectional shapes (e.g., round, elliptical, square, hexagonal, polygonal, etc.). In some implementations, the tubular chamber 250 is part of a larger vacuum chamber 260 in which the tubular chamber 250 is connected. In some cases, the chamber 250 may be formed in a loop with its ends joined together (e.g., as a torus). Further, the tubular chamber 250 can be formed from multiple pieces that are joined together with seals to form a vacuum-compatible assembly, as described in connection with FIG. 1A through FIG. 3D of international Patent Application PCT/US2022/079394, filed Nov. 7, 2022, titled “Ceramic Fibers for Shielding in Vacuum Chamber Systems and Methods for Using Same,” which application is incorporated herein by reference.

During operation of the system 200, the plasma 205 can contain highly energized, charged particles (e.g., ions, electrons) that may be ejected towards the interior surfaces of the chamber 250. When a charged particle strikes the interior surfaces of the chamber 260, contaminants may be sputtered off the interior surfaces of the chamber and enter the plasma 205. Such contaminants can adversely affect manipulation or use of the plasma 205.

The generation of contaminants may be reduced by forming the chamber walls 252 from materials that are more resistant to sputtering when exposed to charged particles ejected from the plasma 205. Furthermore, in applications where plasma manipulation includes chemical or nuclear interactions that are sensitive to the presence of specific contaminants, the materials forming the chamber walls 252 can be chosen such that, in the event contaminants are generated, the composition of the contaminants do not or minimally react with the plasma 205 in an undesirable manner.

For example, in some applications, the plasma 205 primarily contains hydrogen and helium ions (some of which may fuse together to release energy). Under these conditions, it can be preferable for the chamber walls 252 to be formed from a material that does not contain heavy elements, such as tungsten, that may otherwise take away thermal energy from the plasma. If a magnetic field generated by the coils 230 is used to modify the shape of the plasma 205, the chamber walls 252 can be formed from, at least in part, a dielectric such that the chamber walls 252 do not behave as an electrical conductor that affects the transmission and/or spatial distribution of the magnetic fields in the tubular chamber 250 where the plasma 205 is confined. Examples of material that may be used to form the chamber walls 252 include, but are not limited to, silicon dioxide (SiO₂) and sapphire (Al₂O₃), which can generate less contaminants compared to, for example, metals and elastomers.

In some implementations, the chamber wall 252 can be formed from a combination of materials that may include a dielectric material, ceramic, and/or graphite material. Desirably, the chamber wall 252 is vacuum-compatible (e.g., at least has a surface material with a sufficiently low outgassing rate to permit establishing vacuum levels within the chamber to at least millitorr levels or lower or even to 10⁻⁶ Torr or lower). For example, the chamber wall 252 may include quartz glass, graphite, silicon, silica, silicon nitride, boron nitride, or boron carbide; preferably silica. If the chamber wall 252 comprises silica, the silica may include fully single crystal quartz or fully fused silica glass. In some cases, silica and/or another material can be applied to the chamber wall 252 as a coating 253, depicted in FIG. 1B. For example, the coating 253 can comprise silica that is fused on an inner layer 256 and sintered on an outer layer 254 that contacts the chamber wall 252, as depicted in FIG. 1B. A heat sink 270 (comprising ducts or lines for coolant flow, for example) can be placed in thermal contact with the chamber walls 252.

As described above, the tubular chamber 250 can be part of a larger vacuum chamber 260 with at least one first port 282 to allow gases, particles and/or a plasma to move into and/or out of the tubular chamber 250. The larger vacuum chamber 260 can include at least one plasma source 290 to form and inject at least one plasma into the tubular chamber 250, for example. The chamber 250 can have separate ports for different gases, particles and/or plasmas. The chamber 250 can have a second port 284 for introducing and/or removing the gases, particles and/or plasmas into and/or out of the tubular chamber 250. The tubular chamber 250 and/or vacuum chamber 260 can be fluidically coupled to at least one vacuum pump (not shown) through at least one port to create a vacuum environment within the tubular chamber 250 that will support a plasma. In some cases, at least one port on the tubular chamber 250 can function as both an inlet and outlet port for exchanging at least one of a gas, plasma, and/or particles. In some cases, the inlets and outlets may be connected to or include valving (e.g., to close and form a vacuum seal at the port).

The chamber walls 252 can have a thickness that is sufficient to provide structural stability to withstand the mechanical forces imposed via the vacuum (e.g., 15 psi or higher if the external pressure is greater than atmosphere), while permitting the magnetic field to efficiently pass through its walls 252. In some applications, the wall material is silica, and the wall thickness is about 5 mm to about 10 mm. The wall thickness can depend, at least in part, upon the size and shape of the chamber. For example, a tubular chamber 250 in the shape of a cylinder with a larger radius R can have thicker walls for structural reasons than a comparable cylindrical chamber with a smaller radius R. If the tubular chamber 250 has flat surfaces (such as would occur with a hexagonal cross-section), the wall thickness can be greater than a tubular chamber 250 of the same diameter having a circular cross-section. As an example, for systems that measure from approximately or exactly 0.1 meter to approximately or exactly 6 meters in length and from approximately or exactly 0.01 meter to approximately or exactly 3 meters in width (e.g., diameter with a circular cross section), the wall thickness is at least about 1 mm to about 10 mm. Although the chamber walls 252 can be made thicker than is necessary to withstand the atmospheric pressure acting on the tubular chamber or other considerations (e.g., seismic), it can be beneficial to reduce the wall thickness, due to cost and weight considerations among other reasons, to a value for an application that sufficiently withstands the atmospheric pressure acting on the chamber walls 252. An additional consideration is heat transfer through the chamber walls 252, as discussed further below. Reducing wall thickness can improve heat transfer through the chamber walls 252 to a heat sink 270 located on the exterior of the chamber walls.

Each of the electromagnetic coils 230 may be fed with electrical current from one or more supply circuits 220-1, 220-2, 220-3 (only one supply circuit is shown for each electromagnetic coil to simplify the illustration of FIG. 1A). The current may be provided over one or more supply lines 225 connected to each coil. For some applications, the peak amount of current delivered to each electromagnetic coil can be between 1 amp (A) and 200,000,000 A. If other confinement or acceleration apparatus is used (such as electrodes or lasers) in addition to or instead of the electromagnetic coils 230, they may be driven by the supply circuits 220 and controller 210.

Each of the supply circuits 220 can include an electrical source (e.g., a voltage source), at least one energy-storage component (such as a capacitor), and at least one switch that gates the flow of current from the at least one energy-storage component to the associated electromagnetic coil. The switch(es) in each supply circuit may be controlled independently of the switch(es) in other supply circuits 220 in the system. As such, the current waveform and timing of the waveform delivered to each of the electromagnetic coils 230 can be controlled independently, to a significant extent, of the current delivered to other electromagnetic coils 230 in the system 200. This can provide pulsing of the electromagnetic coils to accelerate the plasma. In some cases, structural limitations of the system 200 may limit the amount of variation in amplitude, waveform, and/or timing between two or more of the electromagnetic coils 130. In practice, the electromagnetic coils may also operate in a steady state capacity to confine the plasma, and the charged particles within may be accelerated or heated via alternative means, including via lasers, neutral beam injection, or RF heating.

A controller 210 can communicate with at least one of the supply circuits 220 to control the delivery of current from at least one supply circuit to one or more of the electromagnetic coils 230 (e.g., by activating the supply circuit's switch(es)). The controller 210 may comprise a computer in some cases. In other cases, the controller may comprise a field-programmable gate array, a programmable logic circuit, an application-specific integrated circuit, a digital signal processor, logic circuitry, analog circuitry, or some combination thereof.

In some cases, the control of current delivery to the electromagnetic coils 230 may be distributed among the supply circuits or among firing-control circuits coupled to the supply circuits. For example, the controller 210 may issue a command to deliver current to a first coil 230-1. The command may be received by the first supply circuit 220-1 or a firing-control circuit coupled to the first supply circuit. Likewise, the controller 210 may issue commands to deliver current to other coils 230 in the system. Once the first coil 230-1 is fired, a firing-control circuit may issue firing commands to one or more other supply circuits 220 or firing-control circuits coupled to other supply circuits 220. In this manner, all electromagnetic coils can be fired. Independent control (at least to some extent) of energizing each of the electromagnetic coils 230 is possible with the particle manipulation system 200 of FIG. 1A. With such independent control of the amplitude, waveform, and timing of current delivered to each of the electromagnetic coils 230, dynamic and pulsating, intense magnetic fields can be produced in the chamber 250. Because the electromagnetic coils 230 are independently controlled, the strength and shape of the local electric and magnetic fields in the chamber 250 are highly tunable.

Without being limited by any theory in particular, during confinement, compression, and/or acceleration of plasmas or particles within the particle manipulation system 200, the chamber's inner walls can be exposed to bombardment by high-energy particles and/or radiation including, among other things, bremsstrahlung radiation in the form of X-ray radiation and even gamma ray radiation in some cases. Electrons operating at keV ranges (e.g., 1 keV to 10 keV, including 5 keV) emit Bremsstrahlung radiation in the form of high-energy X-rays (e.g., having energies in excess of 1 keV). Other types of high-energy X-ray emission including activation decay, synchrotron radiation, cyclotron radiation, and beta decay may also occur in these systems. Further, electron excitation during ionization or recombination may also generate high-energy photons, such as X-rays. X-ray radiation emitted during operation of the system 200 presents a structural and operational challenge since X-rays can be absorbed by the chamber walls 252 and potentially create high levels of heat in the chamber walls. Such high heat, if not dissipated quickly, can build up an damage the chamber walls and/or desorb contaminants from the chamber walls that may interfere with manipulation of the plasma 205.

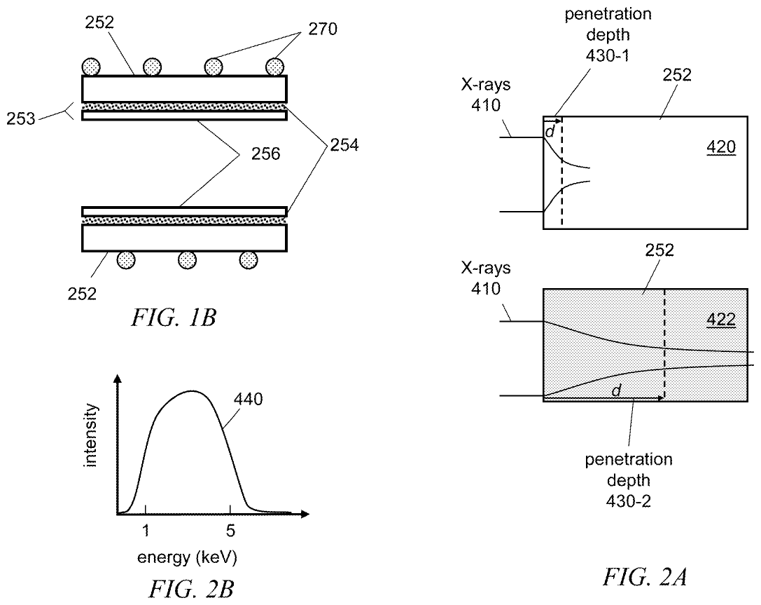

The average distance the X-ray radiation travels into the chamber wall before significant absorption occurs is described by the penetration depth, also sometimes called the skin depth, which is depicted in FIG. 2A. The penetration depth 430-1, 430-2 is defined as the distance d from the material surface on which the radiation is incident to a location in the material at which the intensity of the X-ray radiation 410 falls to 1/e of its original value, or about 37% of the initial value due to attenuation of the radiation by the material. The penetration depth is largely a function of the wavelength of the incident radiation and material properties (such as atomic number and density for absorption of X-rays). Materials with higher atomic number elements and materials with higher densities typically have shorter penetration depths primarily because there are more electrons available per unit volume to absorb the X-rays. As an example, the penetration depth of 5 keV X-rays in silica is about 40 μm.

When absorbed, X-ray energy is converted into heat, which can cause significant heating within the chamber for some applications. During operation of the system 200, pulsed or continuous X-rays may be emitted. Without careful management, the excess heat from the absorbed X-rays can cause dangerous temperature increases, potentially leading to material fracturing or sublimation, and system failure. Conventional heat management within the system includes cooling the outer surface of the chamber using a high-speed cooling apparatus (e.g., liquid cooling tubing) in thermal communication with the outer surface of the chamber. However, cooling the outer surface of the chamber is often not sufficient to prevent a steady increase in the average temperature of the interior wall surfaces of the chamber walls 252 during operation of the system 200. The rising temperature can limit system operational time-when an upper temperature limit is reached, operation is stopped to allow the system to cool down.

Without being bound by any particular theory, localized increasing temperature of the chamber walls 252 (e.g., near its inner surface) can indicate that the rate of heat transfer out of the chamber walls 252 is not fast enough to keep up with the rate of heat generated by absorbed X-ray radiation. The rate of heat transfer is dependent on the thermal conductivity of the chamber wall 252 and the distance through which the heat must transfer to the outer chamber wall where cooling lines can provide a heat sink 270. As the thermal conductivity increases, the rate of heat transfer increases. The heat transfer distance is determined by the thickness of the chamber wall 252 and the penetration depth 430-1, 430-2 of the X-ray radiation 410. As the penetration depth relative to the total chamber wall thickness increases, heat is deposited further into the chamber walls 252 and the heat transfer distance effectively decreases.

As described above, the penetration depth of 5 keV X-rays in silica is about 40 μm and less for lower-energy X-rays, meaning that most of the X-ray energy in this range of energies is absorbed in much less than 0.05 mm of a conventional chamber wall thickness of about 5 mm. This is less than 1% of the thickness of the chamber wall and effectively means that all heat is deposited at the interior surfaces of the chamber walls 252 if the incident X-ray spectrum consists essentially of X-rays up to about 5 keV energy. Since silica has a low thermal conductivity, the heat generated from X-ray absorption takes a long time to transfer through the silica to the outer wall surface. If the X-ray radiation intensity is high enough to generate heat in the silica at a faster rate than the rate of heat transfer through the silica, then the heat accumulates in the silica, localized at the penetration depth, which can lead to structural failure of the chamber wall, and from there potential operational failure of the entire particle manipulation system.

There are several potential approaches to managing heat transfer through the plasma containment chamber wall. One approach is to change the chamber's thermal conductivity. The thermal conductivity of the chamber wall may be changed by changing the chamber's material and/or density. The chamber material choice is somewhat limited and changes to material density may have negative structural and/or vacuum consequences. The density of some materials (such as ceramics or glasses) may be changed by altering the process used to make the material (e.g., changing a baking condition and/or doping concentration). Typically, materials with higher thermal conductivity (e.g., metals) also conduct electricity and negatively affect the magnetic field, so that most thermally conductive materials are inappropriate for the particle manipulation system 200 described above. Preferably, the chamber material is dielectric and/or ceramic, vacuum-compatible, and structurally supportive. Alternatively or additionally, at least part of the chamber material can be graphite. Because the chamber material is dielectric or ceramic, it typically has a low thermal conductivity, so that the rate of heat transfer is slow. Without being bound by any particular theory, this is because the lattice structure properties of a dielectric or ceramic that inhibit electrical conductivity generally also inhibit thermal conductivity. The use of dielectric or ceramic materials to construct the chamber in its entirety may face challenges, including those related to cost and/or structural stability.

A second approach to tuning the rate of heat transfer is to change the distance through which the heat must transfer to reach a heat sink 270. In the context of a plasma containment chamber, a heat sink 270 such as a water or oil coolant system can be placed on the outside of the chamber walls 252. Reducing the distance that the heat must travel from the X-ray penetration depth to the outer chamber wall surface can be accomplished by reducing the thickness of the chamber walls 252. While a thinner chamber wall reduces the distance to the heat sink, it may also compromise the structural integrity of the tubular chamber 250 to withstand atmospheric pressure acting on the chamber. If the chamber is too thin, it cannot withstand the pressure difference between the interior of the chamber and the exterior of the chamber (e.g., 15 psi in the case of an exterior pressure at atmosphere pressure).

A third approach to improving the rate of heat transfer away from the interior of the tubular chamber 250 is to select material (or materials) for the chamber walls 252 of the tubular chamber 250 that has (have) a longer X-ray penetration depth. With a longer penetration depth, X-rays travel farther into the chamber wall and deposit heat farther into the chamber walls 252, closer to the heat sink 270 at the exterior of the tubular chamber 250. Given that X-ray absorption is statistical in nature, extending the penetration depth increases the overall volume the X-rays are absorbed over. To illustrate, if the penetration depth doubles, then the same amount of heat is deposited in significantly more material (e.g., approximately twice the volume of material) so that the peak temperature increase at locations where the X-rays are absorbed in the chamber walls 252 (such as near the inner surface) is significantly reduced (e.g., stays below the melting point of material in the chamber walls 252 and coating 251). Furthermore, the longer the penetration depth, the shorter the distance the deposited heat must transfer to reach the outer chamber wall surface, where a heat sink can be located.

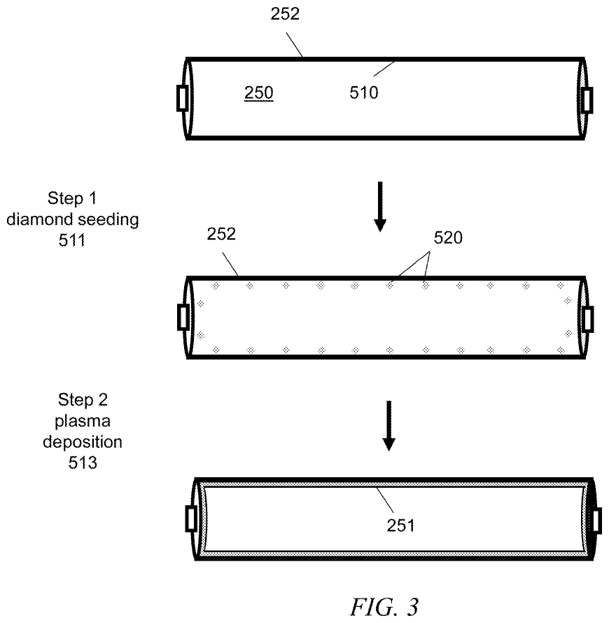

Unfortunately, as mentioned above, the choice of material for making the chamber walls 252 is limited by material properties to candidate materials suitable for the application (e.g., materials that are dielectric, have sufficient strength, and are vacuum compatible), so that the chamber material cannot be chosen based on the X-ray penetration depth alone. However, as disclosed herein, a coating 251 of material (such as the coating shown in FIG. 3) having a longer penetration depth than that of the material used to form the bulk portion of the chamber wall 252 can be applied on the inner surface of the chamber wall 252. The coating 251 can comprise one or more layers of material(s).

According to aspects disclosed herein, instead of or in addition to selecting the bulk material for the chamber wall 252 itself based, at least in part, on X-ray penetration depth, the chamber's inner surface is coated with a film/coating of at least one material that provides a longer X-ray penetration depth than the penetration depth of the bulk material in the chamber wall 252. The coating can have a thickness from approximately or exactly 1 μm to approximately or exactly 2000 μm, though the coating can be thicker in some cases (e.g., for applications where higher energy X-rays that penetrate farther into the material are present in the chamber 250, or for cases where the thickness of the chamber wall 252 can be reduced and replaced by the coating to improve thermal conductivity, or where the chamber wall 252 can be entirely replaced with the coating material, forming a chamber from the coating material). In some cases, the coating 251 can have a thickness from approximately or exactly 50 μm to approximately or exactly 1000 μm. In some cases, the coating 251 can have a thickness from approximately or exactly 100 μm to approximately or exactly 700 μm. For some example coating applications, such as to address X-ray Bremsstrahlung radiation from 1 keV to 5 keV electrons impinging upon a 5 mm quartz or silica wall, the preferred coating has a thickness between 100 μm and 300 μm, for example about 200 μm (e.g., for a diamond or bort coating). Depending on material used for the coating, the thickness of the coating may be no less than 50 microns, no less than 100 microns, no less than 200 microns, no less than 500 microns, or no less than 1 millimeter, though thicker coating may be used in some cases.

By depositing a coating 251 that permits a deeper penetration of the X-rays, X-rays are absorbed across a greater volume of material at the chamber wall. In some embodiments, the coating is thicker than the penetration depth and the X-ray energy is absorbed primarily in the coating. For example, in some applications the thickness of the coating 251 can be from one-half of a penetration depth to five penetration depths or more, where the penetration depth is determined from the coating material and the most abundant energy level (or predominant wavelength) of X-rays incident on the coating 251. The most abundant energy level (or predominant wavelength) can be determined by examining the spectrum of X-ray emissions incident or intended to be incident on the chamber walls 252. In some cases, the penetration depth is determined for one or more X-ray energies of concern from all X-ray wavelengths incident on the chamber wall 252 (e.g., energies that are absorbed near the inner surface of the chamber wall causing the most heating near the inner surface and therefore most likely to damage the inner surface.

The increase in material over which X-rays are absorbed can decrease the peak temperature reached in the chamber wall 252. For example, the coating 251 can be the primary recipient of the X-ray energy as most X-rays can be absorbed by the coating material (when the thickness of the coating is at least one penetration depth), instead of other material(s) making up the bulk of the chamber wall 252. Absorbing most of the X-rays in the coating 251 and generating most of the heat in the coating can provide a benefit where the coating material has a higher heat tolerance (higher thermal damage threshold) and/or higher thermal conductivity than other materials making up the bulk of the chamber wall 252. In some cases, the thickness of the coating can be less than one penetration depth (e.g., at least one-half the penetration depth or from 0.2 penetration depth to one penetration depth).

In some implementations, the thickness of the coating is such that X-rays having a range of energies that would otherwise be absorbed near the inner surface of the chamber wall 252 are mostly absorbed in the coating. For example, the thickness of the coating can be at least one-half a penetration depth for X-rays having the range of energies and having a probability of at least 50% of being absorbed (or for which at least 50% at essentially all energies within the range of energies are absorbed) within a distance D of the inner surface of the chamber wall 252 if the coating 251 were not present. The distance D can be a value in a range from approximately or exactly 50 microns to approximately or exactly 2 millimeters, including values such as 100 microns, 200 microns, 500 microns, and 1 millimeter, for example. Alternatively, the distance D can be a fraction of the thickness of the chamber wall, for example from approximately or exactly 1% of the wall thickness to approximately or exactly 50% of the thickness of the chamber wall, including values such as 10%, 20%, 30%, and 40%, for example. X-rays having the range of energies could have energies in a range from 1 keV to 5 keV for some applications, from 1 keV to 10 keV for some applications, from 1 keV to 20 keV for some implementations, and from 1 keV to 50 keV for some cases, though any subrange within a range from 0.2 keV to 100 keV is possible.

The thickness of the coating could be determined as follows. In this example, X-rays are incident on a chamber wall and a portion of the X-ray spectrum extends form 1 keV to 5 keV (as an example range of energies). X-rays in this portion of the spectrum can generate significant heat near the inner surface of the chamber wall 252, because their penetration depth in silica (as an example material for the chamber wall) is less than 50 microns. At least 50% of X-rays in this energy range would be absorbed within 50 microns of the inner surface of the chamber wall 252. A coating thickness can then be selected for this range of energies. For a boron nitride coating, the penetration depth is about 200 microns for a 5 keV X-ray and less for lower-energy X-rays. Therefore, a coating thickness of one-half the penetration depth of the coating for X-rays in this example range of energies would be about 100 microns. Such a coating could absorb an appreciable amount of the X-rays in the example range of energies that would otherwise be absorbed in and near the surface of the chamber wall. This absorption of X-rays by the coating can reduce heat generation and peak temperatures in the chamber wall and near the surface of the chamber wall 252.

FIG. 2A illustrates differences in X-ray penetration depth for two different materials. In a conventional chamber having a chamber wall 252 made of silica (silicon dioxide) 420, X-ray radiation 410 having an energy of about 5 keV penetrates about 40 μm into the chamber wall 252 before the intensity drops by 1/e., called the penetration depth 430-1. A chamber wall 252 made from a different material 422 (e.g., boron nitride) has a longer penetration depth 430-2 (over 200 microns at 5 keV) so that the X-rays 410 travel farther into the chamber wall 252 and generate heat over a larger volume. Accordingly, the peak temperature reached in the smaller volume for silica 420 will be higher than the peak temperature reached over the larger volume for the different material 422, assuming the two materials have the same thermal conductivity. In this example, boron nitride can have a thermal conductivity that is 30 times or more than that of silica, so that the boron nitride can also transfer the heat away from the volume where heat is generated much more quickly than silica dioxide, further reducing the peak temperature that would otherwise occur in the chamber wall 252 without the coating and improving heat management.

Because the coating 251 has a longer penetration depth, energy can be absorbed across a larger amount of material. In some cases, the heat can be generated mostly (e.g., more than 50% of the generated heat) or even generated completely in the interior coating 251, where most or all of the incident X-rays are absorbed, respectively. In some cases, at least some heat is generated in the chamber wall 252 where some X-rays may be absorbed. Likewise, because the coating has a higher thermal conductivity, it transfers the heat more quickly through it, as described in the example with silica and boron nitride relating to FIG. 2A. The aspects of a larger absorption volume and higher thermal conductivity reduce localized temperature increases in the chamber wall from X-ray absorption during system operation. Further, as lower energy X-rays are absorbed in even thinner layers, the thermal conduction effects can play a larger role in transporting heat away from hot spots in the coating 251. For lower energy X-rays, increased thermal conduction of the coating 251 may be more beneficial for managing heat than X-ray absorption over a larger volume.

Operation of particle manipulation systems 200 that can produce X-ray emission can include pulsed or continuous X-ray emission. The pulse repetition rate and/or power level at which the system operates can depend upon thermal management in the chamber walls 252 of the tubular chamber 250. The system 200 should operate at a level for which heat generated by X-ray absorption in the coating 251 and/or chamber walls 252 is adequately dissipated before reaching a level that could damage the coating 251 and/or chamber walls 252 or adversely affect manipulation of the plasma 205 (e.g., by emitting contaminants). Therefore, the coating 251 can reduce localized peak temperature increases in the chamber walls 252 from a single X-ray pulse, from many X-ray pulses, and from continuous X-ray emission allow the system 200 to be operated at higher pulse repetition rates and/or power levels than it would otherwise operate without the coating 251.

For some applications, a spectrum of X-rays (having a range of energies and wavelengths) can be emitted during operation of the system 200. The emitted X-ray can be characterized by a spectrum 440 (intensity or power vs. energy or wavelength) which may be Gaussian shaped or have another shape as depicted in the energy spectrum of FIG. 2B. The illustrated energy spectrum 440 has a full-width-half-maximum (FWHM) value of 4 keV that extends from 1 keV to 5 keV. In some cases, a significant portion of the heat generated in a coating or wall can be due to X-ray absorption from the lower energy part of the X-ray spectrum 440. Because lower-energy X-rays can have a shorter penetration depth into any given material than higher-energy X-rays, the lower energy X-rays can be deposited into a smaller volume of the coating 251 than the higher-energy X-rays. In some cases (e.g., during pulsed operation), the absorption of the lower-energy X-rays can lead to a higher localized temperature increase than absorption of the higher-energy X-rays. Selecting a coating with a high thermal conductivity (e.g., greater than 5 W m⁻¹ K⁻¹) can transport heat generated by the lower-energy X-rays through the coating very quickly to reduce localized peak temperatures not just in aggregate over time, but also during individual pulses when the system 200 is operated in pulse mode.

In addition to having a long penetration depth (e.g., greater than 50 microns) and high thermal conductivity, the coating material preferably is also dielectric and vacuum-compatible. Not many materials have all these properties. Most dielectric materials, like silica, have low thermal conductivities. That is, very few materials conduct heat but do not conduct electrons. One of the few exceptions is diamond, which is a dielectric material that conducts heat via lattice vibrations. Diamond also has a longer X-ray penetration depth than silica given carbon's lower atomic number than either silicon or oxygen. Accordingly, the coating 251 can be diamond and/or comprise diamond-like carbon, known as bort.

Diamond has favorable thermal properties for particle manipulation systems. In contrast to metals, where conduction electrons are responsible for the high thermal conductivity, dielectric crystalline materials like diamond conduct heat by lattice vibrations. With a sound velocity of 17500 m/s, diamond is the material with the highest Debye temperature (2220 K), exceeding that of most other insulating materials by an order of magnitude. Debye temperature is good approximation for the low temperature heat capacity of insulating, crystalline solids where other contributions (such as highly mobile conduction electrons) are negligible. Diamond has the highest thermal conductivity of any material at room temperature (2000-2500 W m⁻¹K⁻¹), exceeding that of copper by a factor of five. Diamond and bort have X-ray penetration depths of approximately 200 microns for X-ray energies of about 5 keV.

Diamond has other properties that are favorable for use as a coating 251 in the particle manipulation system 200. Diamond is an extremely hard material, and thus may not substantially sputter or degrade when interacting with the plasma. In some embodiments, the diamond coating 251 may also aid structural stability of the chamber, allowing the thickness of the chamber wall 252 to be reduced. Diamond also has a low dielectric constant of 5.7, a loss tangent below 0.00005 at 145 GHz and a high dielectric strength of 1,000,000 V/cm.

Bort, or diamond-like carbon, is non-gem-grade diamond with a semi-crystalline disordered or amorphous crystal structure. It has a significant amount of sp³ hybridized carbon atoms. For example, at least 30% of the carbon atoms can be sp³ hybridized in a bort coating 251. It can also include higher amounts of impurities than diamond. Impurities include other forms of carbon (e.g., graphitic sp² hybridized carbon) and hydrogen (e.g., protium or deuterium). While pure diamond has a cubic crystal structure, bort can have a mix of cubic and hexagonal crystal structures. Bort may have no long-range crystalline order. Though structurally different compared to diamond, bort has somewhat similar electrical, thermal, X-ray and mechanical properties.

### 2. Bort Coatings

The fundamental problem of diamond synthesis is the allotropic nature of carbon. Graphite is a more thermodynamically stable crystalline phase of carbon than diamond. Because of the higher stability of graphite, diamond and bort are deposited using techniques to suppress the formation of graphitic sp²-bonds. High concentrations of non-diamond carbon etchants (e.g., atomic protium and/or atomic deuterium) are used to suppress the formation of graphitic sp²-bonds. Atomic protium and/or atomic deuterium are made by dissociating protium gas (H₂) or deuterium gas, that is activated either thermally or with a plasma. Atomic protium and/or atomic deuterium selectively etches graphite and breaks up double bonds, thus converting graphitic sp² bonds into diamond sp³ bonds.

Diamond and bort thin films can be deposited using plasma-enhanced chemical vapor deposition (PECVD). PECVD is a chemical vapor deposition process used to deposit thin films from a gas state to a solid state on a substrate. Chemical reactions are involved in the process, which occur after creation of a plasma of the reacting gases. PECVD involves surface reactions with gas-phase precursors at nonequilibrium. The precursors are protium gas and/or deuterium gas and one or more hydrocarbons. These precursors are activated by the plasma to form atomic protium and/or deuterium gas and hydrocarbon radicals.

Typically, PECVD of diamond is limited to surface areas of about 450 mm or less. This is because PECVD typically aims to produce diamond thin films with high purity, crystallinity, and precise thickness, which are useful for particular applications, including optics and integrated circuit manufacturing. For these higher purity thin films, the stability competition between graphite and diamond is a factor. Moreover, as the size of the substrate increases, the difficulty in maintaining an even ion flux across the entire substrate increases, limiting PECVD surface area and adding to the difficulty of scaling high purity diamond deposition.

For applications where the coating does not need a high purity or precise thickness, diamond can be deposited on much larger surface areas and with greater thicknesses. Though less pure, diamond and/or bort coatings deposited on large surface areas can have improved structural strength, electrical resistance, and/or thermal conductivity compared to silica. For example, some particle manipulation systems 200 described herein can tolerate a coating 251 with high impurity levels of protium, deuterium, and graphite impurities in the diamond and/or bort (e.g., up to about 50% graphite impurity). The system 200 can also tolerate high variability (e.g., up to about 50% variation) in coating thickness across the inner surface of the chamber wall 252.

FIG. 3 shows an example bort deposition process to coat at least a portion of the inner surface 510 of a chamber 250. In the first step 511, prior to deposition, the inner surface 510 of the chamber 250 is pre-treated with microscopic diamond seed crystals 520. Diamond seeding facilitates diamond formation during deposition. One way to seed is to polish the surface with diamond powder so that microscopic diamond crystals remain on the surface. During a subsequent PECVD process 513, the diamond crystals increase in size until they form a continuous, compact coating 251 of polycrystalline diamond on the inner surface 510.

After the inner surface 510 of the chamber 250 is seeded with diamond seed crystals 520, the coating 251 can be formed on the inner surface of the chamber with the PECVD process 513. Prior to deposition, the chamber 250 is purged to remove residual gases inside of the chamber. The temperature of the chamber 250 during deposition may be in a range from approximately or exactly 25° C. to approximately or exactly 2500° C., for example. In one embodiment, the chamber 250 is heated to one or more temperatures in a range from approximately or exactly 700° C. to approximately or exactly 2500° C. and the pressure inside the chamber 250 may be in a range from approximately or exactly 1 Torr to approximately or exactly 500 Torr, for example, during deposition. In some cases, the chamber 250 can be heated to one or more temperatures in a range from approximately or exactly 300° C. to approximately or exactly 1000° C. during deposition of the coating 251. The chamber 250 may be heated by the RF plasma used for PECVD and/or by inductively heating a resistive layer (e.g., graphite) in the chamber wall or in contact with the chamber wall 252. The resistive layer can be adjacent to or at the inner surface 510 of the chamber 250 in some cases. In some implementations, the resistive layer can be discontinuous around the circumference of the chamber 250 to suppress eddy currents that would otherwise be generated by the magnetic field produced by the coils 230. Alternatively, the chamber 250 may be heated via a rotosil-type process, where an intense electrical arc is initiated in the plasma to generate infrared light, which is absorbed in a near-surface inner layer of the chamber wall 252. In some cases, the chamber 250 can be placed in an oven for deposition or heated by heating elements thermally coupled to an exterior of the chamber 250.

A process gas, which can comprise a mixture of gases, is introduced into the chamber 250 during deposition of the bort and/or diamond coating 251. The process gas may be held statically or continuously flowed through the chamber during deposition. The process gas mixture includes at least one of protium or deuterium and at least one hydrocarbon or deuterated hydrocarbon. For example, the hydrocarbon may be methane, acetylene, silane, or deuterated versions thereof. The hydrocarbon or deuterated hydrocarbon is present in the gas mixture with a stoichiometric ratio from approximately or exactly 0.001:1 to approximately or exactly 0.1:1 relative to the protium and/or deuterium, for example. Deuterated precursor gases may be used here because protium is an impurity in some plasma confinement processes. The process gas mixture may also include other gases to promote particular carbon phases (e.g., water, oxygen, carbon dioxide), and/or one or more inert gases (e.g., argon, nitrogen, sulfur hexafluoride).

The plasma is initiated in the process gas. A microwave or radiofrequency (RF) plasma discharge dissociates and ionizes the gases that then deposits as pure carbon, forming polycrystalline diamond and bort (diamond-like carbon) combinations of C—C and C—C: H on the inner surface of the chamber. The RF plasma source may include electrodes that do not introduce metallic impurities, including carbon electrodes (e.g., graphite or graphene). The RF plasma source may operate continuously or in a pulsed manner. Plasma discharges may be pulsed-high intensity RF waves at a frequency from approximately or exactly 0.1 MHz to approximately or exactly 10 MHZ, for example, and at RF power levels from approximately or exactly 0.1 GW to approximately or exactly 10 GW (e.g., 1 GW), for example. In some cases, plasma discharges may be may steady, continuous RF wave having a frequency from approximately or exactly 100 MHz to approximately or exactly 3000 MHZ, for example, at a power level from approximately or exactly 10 kW to approximately or exactly 100 kW, for example. A pulsed plasma discharge may be preferable because it provides higher intensity RF field using similar amounts of energy as compared to continuous discharge. The plasma may be directed toward the inner surfaces 510 of the chamber walls 252 with external electromagnetic coils positioned near the exterior of the chamber. In an example where the chamber 250 has a tubular shape, external electromagnetic coils may not be needed to direct the plasma toward the inner surfaces of the chamber walls. In an embodiment, the deposition rate of the coating 251 (increase in coating thickness) may be in a range from approximately or exactly 10 μm per hour to approximately or exactly 100 μm per hour, for example, when depositing bort or diamond. In another embodiment, the growth rate is slower. The coating may have a thickness from approximately or exactly 1 μm to approximately or exactly 2000 μm, including all values and sub-ranges in between. In some cases, the coating 251 can be thicker than 2000 μm.

In some implementations, the coating is treated after deposition. For example, the coating may be heated to crystallize or fuse deposited material. Alternatively or additionally, the coating may be polished after it is formed (e.g., mechanically polished or using a chemical-mechanical polishing process).

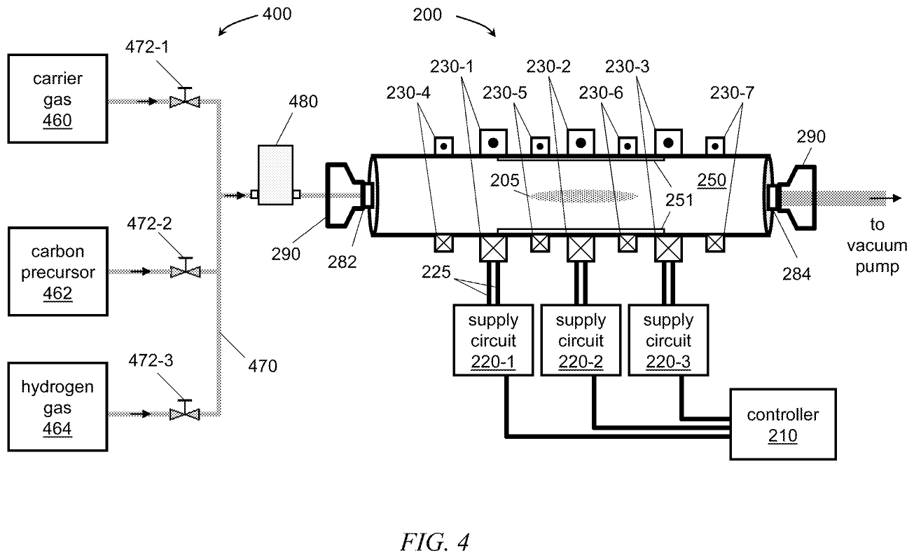

In some cases, to provide a more uniform coating, the coating can be deposited on the inner surface 510 of the chamber 250 in sections. For example, sections of the inner surface 510 of the chamber 250 may be covered prior to deposition (e.g., with quartz fiber tape or quartz fiber film) so that the coating is not deposited on those sections. At least one section of the inner surface 510 is not covered to allow coating deposition on the section(s). The section(s) can then be covered after deposition of the coating. The tape or film covering another section (or other sections) can be removed for a subsequent coating deposition. The tape or film has sufficient mechanical strength to withstand the forces used to break the coating to remove the tape or film. In some cases, only a portion of the inner surface 510 of the chamber wall 252 may be coated, as depicted in FIG. 4. The portion coated may be a portion of the chamber 250 centered around a region of the chamber where a plasma 205 within the chamber is compressed to its smallest spatial extent during operation of the system. Other portions of the chamber can be blocked off to prevent deposition of the coating 251, for example.

### 3. Deposition System

FIG. 4 shows an example particle manipulation system 200 having a containment chamber 250 to contain particles, such as atoms of a plasma. The particle manipulation system 200 can have all the features and functionality of the particle manipulation system 200 of FIG. 1A and need not be described again. In the illustration of FIG. 4, the particle manipulation system 200 fluidically couples to gas supply apparatus 400 that can adapt the particle manipulation system 200 for in situ deposition (e.g., PECVD) of bort, diamond, and/or graphite in the tubular chamber 250.

The inlet 282 to the tubular chamber 250 can be fluidically coupled, via tubing 470, to different gas supplies 460, 462, 464 that provide gases and a gas mixture for deposition of the coating 251. The gas supplies can include a carrier gas 460, a carbon precursor 462 (also referred to here as a hydrocarbon or deuterated hydrocarbon), and a protium gas 464. In place of the protium gas 464, deuterium may be used. Valves 472 are placed between each gas supply 460, 462, 464 and the chamber 250. Each valve 472-1, 472-2, 472-3 may be an open/close valve (e.g., a ball valve, a butterfly valve, a gate valve, or a diaphragm valve) and/or a metering valve. In some implementations, the valves 472 are communicatively coupled to and controlled by the controller 210, though they may be coupled to and controlled by a separate controller for the gas supply apparatus 400. The system 200 also includes a pressure controller 480 upstream of the chamber to control the pressure in the chamber 250. The pressure controller 480 includes sensors that may measure the pressure upstream of the chamber, downstream of the chamber, and/or within the chamber. The outlet 284 is coupled to a vacuum pump to provide a vacuum within the chamber.

In some implementations, there can be at least some of the electromagnetic coils 230 that can generate radio-frequency (RF) electromagnetic waves inside the tubular chamber 250 for coating deposition. RF excitation of a gaseous mixture from the gas supplies 460, 462, 464 can create a plasma for PECVD. In some cases, electromagnetic coils 230-4, 230-5, 230-6, 230-7 (supply circuits not shown to simply the drawing) that are used to generate RF waves for PECVD in the tubular chamber 250 for deposition are different (e.g., lower inductance) from the electromagnetic coils 230-1, 230-2, 230-3 used to generate a magnetic field for confining and/or manipulating a plasma inside the chamber 250 that can produce X-rays. Because the electromagnetic coils 230 are independently controlled, the strength and shape of the local RF electromagnetic field in the chamber 250 can be tuned (e.g., to adjust intensity of the RF field at different locations within the chamber 250). This tunability can homogenize ion density distribution in the chamber during deposition, which can improve uniformity of the thickness and/or quality of the deposited coating 251. Simulation tools (e.g., Ansys Maxwell) can be used to model the electromagnetic field throughout the chamber and to determine power settings for the different electromagnetic coils 230 that will homogenize the field intensity to improve uniformity of ion density. Conversely, the RF field can be adjusted to different intensities at different locations within the chamber 250 to spatially vary the thickness of the deposited coating. This may be beneficial if some areas of the chamber receive more radiation and/or deteriorate more quickly than other areas within the chamber.

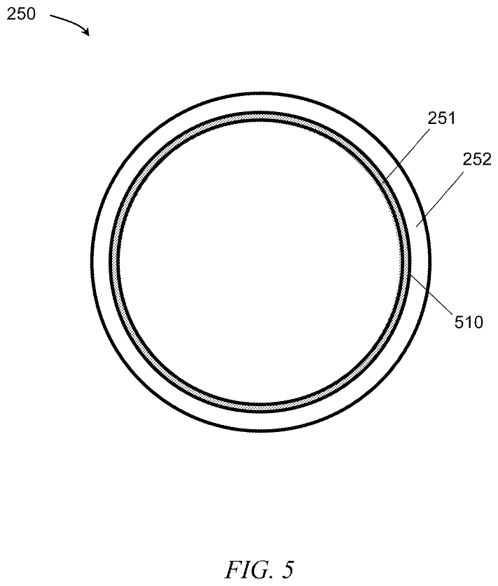

FIG. 5 shows a cross-section of a coated tubular chamber 250 according to some embodiments. The coated chamber includes a bulk silica chamber wall 252 and a bort coating 251 disposed on the inner surface 510 of the silica chamber wall 252. The coating 251 has a thickness of about 1 μm to about 2000 μm or greater. Preferably, the coating has a thickness of about 200 μm.

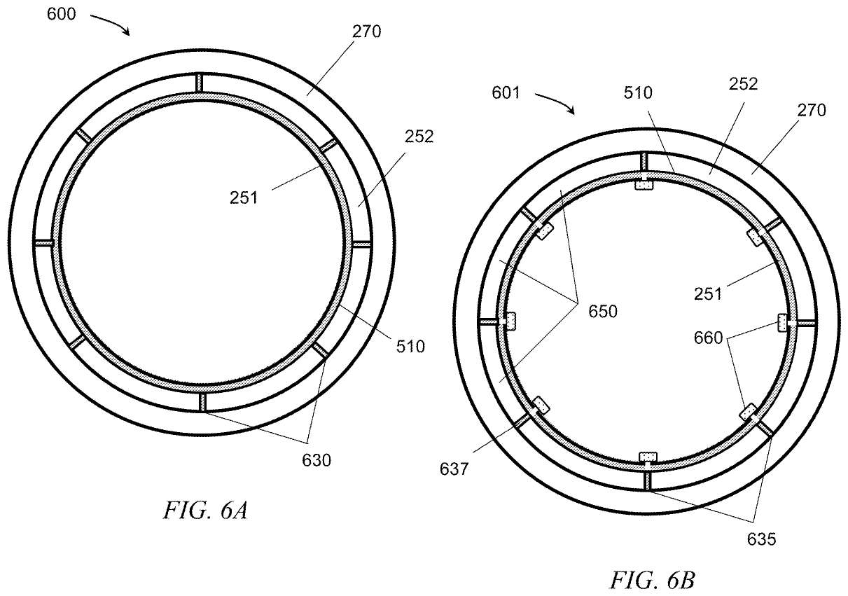

FIG. 6A shows a cross-section of another embodiment of a coated tubular chamber 600. The coated chamber 600 includes a bulk silica chamber wall 252 and a bort coating 251 disposed on the inner surface of the silica chamber wall 252. Channels 630 pass through the silica chamber part-way or entirely wall 252 and are filled with a thermally-conductive filler (e.g., bort, graphene, boron nitride, and/or diamond). In some implementations in which the dielectric requirements are not as pressing, the holes may be filled with a non-magnetic metal (e.g., stainless steel, aluminum, copper). The channels 630 may be formed by mechanical boring, acid etching, or laser boring. The channels 630 may be cylindrical or prism shaped holes, though other shapes are possible. The channels 630 when filled with a material having high thermal conductivity can provide high thermal conductivity pathways between the coating 251 on the inner surface 510 of the chamber and a heat sink 270 on the outer surface. The filler may be formed in the channels 630 via thermal spray coating, PECVD, and/or casting a suspension of filler particles. This configuration can reduce thermal build-up at the interface between the coating 251 and the bulk silica wall 252 and can improve overall thermal conduction from the coating 251 and inner surface 510 to the exterior heat sink 270. Additional transition materials, or filler material (such as quartz rope, quartz tape, ceramic) can be formed between the silica and the channel material to address any issues arising from different rates of thermal expansion with the different materials involved. In some cases, an interlayer material (e.g., graphite or a ceramic) can be deposited on the channel walls before adding the filler to relieve stress arising from different coefficients of thermal expansion between the filler material and the bulk silica wall 252.

FIG. 6B depicts a coated chamber 601 for which the chamber wall 252 is formed from a plurality of sections 650 (e.g., tiles). The tiles can be mounted against the heat sink 270 in some applications or against an outer chamber wall that may or may not support a vacuum. Gaps 635 between the sections 650 can be filled with a vacuum compatible material which could provide a vacuum seal between the sections and/or have a higher thermal conductivity than the bulk material in the chamber wall 252 from which each section 650 is made. In some cases, the filling 637 between the sections 650 comprises a vacuum-compatible elastomer (e.g., nitrile rubber, fluoro-rubber, etc.) or a vacuum-compatible plastic (e.g., fluoropolymers, Kapton, polyetheretherketone, etc.). In some implementations, the filling 637 comprises a dielectric such as bort, diamond, boron nitride, or graphite. In some cases, the filling 637 comprises a conductive, non-magnetic metal (e.g., stainless steel, aluminum, copper, etc.) The filling 637 and gaps 635 can be filled with or covered with a quartz fiber rope or tape 660.

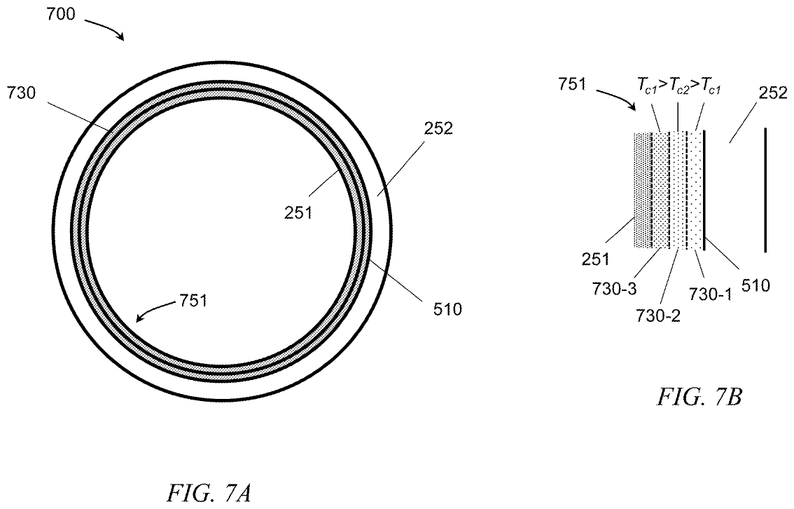

FIG. 7A shows a cross-section of another embodiment of a coated tubular chamber 700. The coated chamber 700 includes a bulk silica chamber wall 252 and a bort coating 251 disposed on an interfacial layer 730 that is disposed between the bort coating 251 and the silica chamber wall 252. The bort coating 251 and the interfacial layer 730 form a multilayer coating 751 on the inner surface 510 of the chamber wall. The interfacial layer 730 can be composed of a material having a thermal conductivity between the thermal conductivity of the bort material in the bort coating 251 and the thermal conductivity of bulk silica wall 252. The material of the interfacial layer 730 may have a different density and carbon purity than the bort coating 251 and the silica wall 252, and in some cases may itself be composed of bort. In this manner, the interfacial layer 730 may reduce or substantially prevents thermal build-up at the interface between the multilayer coating 751 and the bulk silica wall 252.

FIG. 7B depicts another version of a multilayer coating 751 (showing only a portion of a chamber wall 252) where multiple interfacial layers 730-1, 730-2, 730-3 are disposed between the bort coating 251 and the silica chamber wall 252. The interfacial layers 730 can have two or more different thermal conductivities Tc to create a thermal conductivity gradient. For the illustrated example of FIG. 7B, each interfacial layer has a different thermal conductivity and the layers are arranged such that the interfacial layer 730-3 with the highest thermal conductivity is in contact with the inner coating 251 (e.g., a bort coating) and the thermal conductivity values monotonically decrease toward the chamber wall 252. Other arrangements of the thermal conductivity values are also possible and may depend, at least in part, on the penetration depth of X-rays in the interfacial layers 730-1, 730-2, 730-3. In some cases, the interfacial layers may have coefficients of thermal expansion (CTEs) that are between the CTE of the coating 251 and the CTE of the chamber wall 252 to relieve stress that would occur if the coating 251 contacted the chamber wall 252 directly. The one or more interfacial layers 730-1, 730-2, 730-3 may be deposited using the same methods used to deposit the bort coating 251. Alternatively, the interfacial layer(s) may be deposited via thermal spray coating or suspension casting.

Operation of the particle manipulation systems 200 described above may deteriorate the coating 251 over time. For example, coating deterioration can result from plasma impingement, electromagnetic radiation, and mechanical strain due to thermal expansion and contraction. Certain plasma processes may subject the coating to neutron radiation and gamma rays, which may also degrade the coating and/or transmute the coating into other materials less favorable for use as a coating in this system (e.g., smaller X-ray penetration depth, lower thermal conductivity, and/or lower hardness). In some cases, the coating 251 may slowly ablate off the chamber wall. To counteract deterioration, the coating 251, 751 can be refreshed periodically by depositing additional coating material on the inner surface of the chamber wall and/or preexisting coating 251, 751. Where there are multiple coatings (e.g., to form the thermal gradient), frequent refreshing of the innermost layer facing the plasma may help avoid deterioration of the second layer. In some implementations, a new and complete coating 251, 751 can be deposited over the remnants of the preexisting coating 251, 751. The coating may be refreshed at certain time intervals or when certain operation conditions indicate that the coating has deteriorated. Operation conditions that may indicate that the coating has deteriorated include the average temperature within the chamber substantially increasing during operation or when there is a substantial increase in contamination of the plasma as measured by spectroscopy or noticed decreases in performance of the particle manipulation system 200. This refreshing process follows the same process described above to deposit the initial coating 251, 751. In an embodiment, the additional coating layer(s) is (are) deposited onto the existing coating 251, 751, so that the process may forego a diamond seeding pretreatment. In another embodiment, the existing coating 251. 751 is partially or completely removed (e.g., via etching with a plasma created in the plasma chamber) prior to depositing the additional coating material. It may be beneficial to remove at least some of the existing coating 251, 751 if the coating material has been transmuted as a result of neutron radiation exposure. Prior to deposition, plasma confinement operation is stopped, the chamber is purged of any residual gasses, and the chamber walls can be heated to a temperature in a range from approximately or exactly 100° C. to approximately or exactly 1000° C. to drive contaminants from the surface on which the new material will be deposited.

Various coating implementations and related methods are possible, some of which are listed below. The different coating configurations may be used in or produced by any of the listed methods.
(1) A method of containing a plasma in a plasma chamber, the method comprising: injecting a plasma into the plasma chamber; applying a magnetic field to the plasma to manipulate the plasma; receiving, in a coating deposited on an inner surface of a wall of the plasma chamber that faces the plasma, electromagnetic radiation including X-rays from the plasma, a portion of the X-rays having a range of energies, wherein a thickness of the coating is at least one-half a penetration depth for the portion of the X-rays having the range of energies and for which at least 50% of the X-rays having the range of energies are absorbed within 1 millimeter of the inner surface of the wall without the coating present.
(2) The method of (1), wherein the portion of the X-rays having the range of energies have energies within a range from 1 keV to 5 keV.
(3) The method of (1) or (2), wherein the coating has a first thermal conductivity that is higher than a second thermal conductivity of the wall.
(4) The method of (3), wherein the coating comprises at least two layers of material, wherein:
a first layer of the at least two layers comprises at least one of diamond, graphite, or bort and has the first thermal conductivity; and
a second layer of the at least two layers has a third thermal conductivity with a value between the first thermal conductivity and the second thermal conductivity.
(5) The method of any one of (1) through (4), wherein the thickness of the coating is no less than 50 microns.
(6) The method of any one of (1) through (5), wherein the thickness of the coating is up to three penetration depths for the portion of the X-rays having the range of energies.
(7) The method of any one of (1) through (6), wherein the coating comprises at least one of diamond, graphite, boron nitride, or bort.
(8) A plasma chamber to contain a plasma, the plasma chamber comprising: a wall surrounding a volume in which the plasma is contained when the plasma chamber is in operation; and a coating in thermal communication with an inner surface of the wall to receive electromagnetic radiation including X-rays from the volume, a portion of the X-rays having a range of energies, wherein: a first thermal conductivity of the coating is greater than a second thermal conductivity of the wall; a thickness of the coating is at least one-half a penetration depth for X-rays in the range of energies; and at least 50% of the X-rays having the range of energies are absorbed within 1 millimeter of the inner surface of the wall without the coating present.
(9) The plasma chamber of configuration (8), wherein the portion of the X-rays having the range of energies have energies within a range from 1 keV to 5 keV.
(10) The plasma chamber of configuration (8) or (9), wherein the thickness of the coating is up to three penetration depths for the portion of the X-rays having the range of energies.
(11) The plasma chamber of any one of configurations (8) through (10), wherein the thickness of the coating is no less than 50 microns.
(12) The plasma chamber of any one of configurations (8) through (11), wherein the coating comprises at least one of diamond, graphite, boron nitride, or bort.
(13) The plasma chamber of any one of configurations (8) through (12), wherein the coating has a first thermal damage threshold that is higher than a second thermal damage threshold of the wall.
(14) The plasma chamber of any one of configurations (8) through (13), wherein the coating comprises at least two layers of material, wherein: a first layer of the at least two layers comprises at least one of diamond, graphite, or bort and has the first thermal conductivity; and a second layer of the at least two layers has a third thermal conductivity with a value between the first thermal conductivity and the second thermal conductivity.
(15) The plasma chamber of any one of configurations (8) through (14), wherein the wall comprises silica.
(16) A system comprising: the plasma chamber of any one of configurations (8) through (15); a plurality of electromagnetic coils outside the plasma chamber and arranged to create a magnetic field to confine and manipulate the plasma within the plasma chamber; and a heat sink in thermal communication with an exterior surface of the wall of the plasma chamber.
(17) The system of configuration (16), further comprising circuitry to apply current to the plurality of electromagnetic coils such that the plasma is compressed and at least some atoms within the plasma fuse.
(18) The system of configuration (16) or (17), wherein the heat sink comprising ducts in which a coolant can flow.
(19) A system, comprising: a plasma chamber having a wall extending around an inner volume, the plasma chamber adapted to support a vacuum in the inner volume, the wall of the plasma chamber having a thermal conductivity no greater than 5 W m⁻¹ K⁻¹; a plasma source to generate a plasma and to inject the plasma into the inner volume of the plasma chamber; at least one gas inlet coupled to the plasma source, to introduce a gas or a gaseous mixture into the plasma source; and a plurality of electromagnetic coils arranged to generate a magnetic field within the plasma chamber, such that interaction of particles of the plasma with the magnetic field generates electromagnetic radiation including X-rays, a first portion of the X-rays being absorbable by the wall of the plasma chamber to cause heating of the wall; wherein the plasma chamber further includes a coating comprising at least one of bort, boron nitride, graphite, or diamond, the coating disposed on an inner surface of the wall of the plasma chamber to absorb at least a second portion of the X-rays included in the first portion of the X-rays, such that localized peak heating of the wall near the inner surface that occurs during operation of the system due to absorption of the first portion of the X-rays is reduced compared to absorption that would occur of the first portion of the X-rays without having the coating present.
(20) The system of configuration (19), further comprising: at least one supply circuit coupled to the plurality of electromagnetic coils; and at least one controller coupled to the at least one supply circuit to control one or more parameters of the magnetic field.
(21) The system of configuration (19) or (20), wherein the at least one gas inlet comprises a first gas inlet and a second gas inlet, and wherein the system further comprises: a hydrocarbon precursor supply coupled to the first gas inlet to deliver a hydrocarbon precursor to the plasma source; and at least one of a protium supply or a deuterium supply coupled to the second gas inlet to deliver at least one of a protium gas or a deuterium gas to the plasma source.
(22) The system of any one of configurations (19) through (21), wherein the plasma chamber comprises at least one of a dielectric material, a ceramic material, or graphite.
(23) The system of any one of configurations (19) through (22), wherein the plasma chamber comprises quartz.
(24) The system of any one of configurations (19) through (23), wherein the coating is disposed on all exposed surfaces of the inner surface of the wall.
(25) The system of any one of configurations (19) through (24), wherein the coating comprises at least two layers of material, wherein: a first layer of the at least two layers comprises at least one of diamond, graphite, or bort and has a first thermal conductivity; and a second layer of the at least two layers has a second thermal conductivity with a value between the first thermal conductivity and a third thermal conductivity of the wall.
(26) The system of any one of configurations (19) through (25), further comprising quartz fiber tape or rope disposed on at least a portion of the inner surface of the wall.
(27) The system of any one of configurations (19) through (26), wherein the plasma chamber has a diameter in a range from 0.01 meters to 3 meters and a length in a range from 0.2 meters to 6 meters.
(28) The system of any one of configurations (19) through (27), further comprising a resistive layer disposed on at least a portion of a plasma chamber wall, wherein the resistive layer provides inductive heating to the plasma chamber.
(29) The system of any one of configurations (19) through (28), wherein the coating has a thickness no less than 200 microns.
(30) The system of any one of configurations (19) through (29), wherein: the coating has a thickness that is selected to be at least one-half a penetration depth for the coating and for the first portion of the X-rays, and at least 50% of the first portion of the X-rays are absorbed within a distance into the wall that is 20% of the thickness of the wall.
(31) The system of any one of configurations (19) through (30), wherein the coating comprises bort.
(32) The system of any one of configurations (19) through (30), wherein the coating comprises diamond.
(33) The system of any one of configurations (19) through (30), wherein the coating comprises graphite.
(34) The system of any one of configurations (19) through (30), wherein the coating comprises boron nitride.
(35) The system of any one of configurations (19) through (34), further comprising at least one channel disposed through the wall of the plasma chamber, wherein the channel is filled with a material having a higher thermal conductivity than the thermal conductivity of the wall.
(36) The system of any one of configurations (19) through (35), further comprising an interfacial layer disposed between the inner surface of the plasma chamber and the coating, the interfacial layer having a second thermal conductivity different than the thermal conductivity of the wall of the plasma chamber and different from a third thermal conductivity of the coating.
(37) The system of any one of configurations (19) through (36), wherein the electromagnetic radiation includes radiation arising from one or more of: confinement of the plasma by the magnetic field; compression of the plasma by the magnetic field; or acceleration of the plasma by the magnetic field.
(38) The system of any one of configurations (19) through (37), wherein the electromagnetic radiation includes Bremsstrahlung radiation from interactions between the particles of the plasma, from interactions of the particles of the plasma with the magnetic field, or both.
(39) A method of depositing a coating on an inner surface of a wall of a plasma chamber for which electromagnetic radiation including X-rays will be incident on the coating, a portion of the X-rays having a range of energies, the method comprising: heating the plasma chamber such that the inner surface of the wall is at a temperature from 300° C. to 2500° C.; and introducing a gas mixture into the plasma chamber, the gas mixture including: a first gas comprising a hydrocarbon; and a second gas comprising at least one of protium or deuterium; generating a plasma in the plasma chamber; and depositing the coating on the inner surface of the wall; wherein: the coating comprises at least one of diamond, graphite, or bort; and the coating is deposited to a thickness of at least one-half a penetration depth for the portion of X-rays having the range of energies; and at least 50% of the X-rays having the range of energies are absorbed within 1 millimeter of the inner surface of the wall without the coating present.
(40) The method of (39), wherein the portion of the X-rays having the range of energies have energies within a range from 1 keV to 5 keV.
(41) The method of (39) or (40), wherein the thickness of the coating is up to three penetration depths for the portion of the X-rays having the range of energies.
(42) The method of any one of (39) through (41), wherein the thickness of the coating is no less than 50 microns.
(43) The method of any one of (39) through (42), wherein the wall of the plasma chamber comprises silica.
(44) The method of any one of (39) through (43), wherein the coating comprises at least two layers of material, wherein: a first layer of the at least two layers comprises at least one of diamond, graphite, boron nitride, or bort and has a first thermal conductivity; and a second layer of the at least two layers has a second thermal conductivity with a value between the first thermal conductivity and a third thermal conductivity of the wall.
(45) The method of any one of (39) through (44), further comprising pretreating the inner surface of the plasma chamber.
(46) The method of any one of (39) through (45), wherein the generating the plasma includes applying a radio-frequency (RF) electromagnetic wave to the gas mixture in the plasma chamber to dissociate and ionize the gas mixture.
(47) The method of (46), wherein an intensity of the applied RF electromagnetic wave is spatially varied across the plasma chamber to spatially vary the thickness of the coating.
(48) The method of any one of (39) through (47), wherein depositing the coating comprises coating all exposed surface of the inner surface of the plasma chamber.
(49) The method of any one of (39) through (48), further comprising: prior to depositing the coating, blocking at least one portion of the inner surface of the plasma chamber so that the at least one portion of the inner surface is not coated with the coating during the depositing of the coating.
(50) The method of (49), wherein depositing the coating forms the coating in a portion of the plasma chamber centered around a region of the plasma chamber where a plasma within the plasma chamber is compressed to its smallest spatial extent during operation of the plasma chamber.
(51) The method of any one of (39) through (50), wherein the hydrocarbon is at least one of methane, deuterated methane, or silane.
(52) The method of any one of (39) through (51), wherein the second gas is deuterium.
(53) The method of any one of (39) through (52), wherein the generating of the plasma includes generating at least one of a pulsed RF electromagnetic wave or a continuous RF electromagnetic wave.
(54) The method of (53), wherein the pulsed RF electromagnetic wave has a frequency in a range from 0.1 MHz to 10 MHz and a power in a range from 0.1 GW to 10 GW.
(55) The method of (53), wherein the continuous RF electromagnetic wave has a frequency in a range from 100 MHz to 3000 MHZ and a power in a range from 10 kW to 100 kW.
(56) The method of any one of (39) through (55), wherein heating the inner surface comprises heating the inner surface via the plasma.
(57) The method of any one of (39) through (56), wherein heating the inner surface comprises inductively heating the wall of the plasma chamber.
(58) The method of any one of (39) through (57), wherein heating the inner surface comprises generating an infrared light in the plasma chamber.
(59) A method of refreshing a coating on an inner surface of a plasma confinement system, the plasma confinement system comprising: a plasma chamber having a bort coating on at least a portion of an inner surface of the plasma chamber, wherein the bort coating is arranged to receive, from a plasma confined by the plasma confinement system, X-rays having a range of energies; the method comprising: purging the plasma chamber to remove any residual gasses; heating the inner surface of the plasma chamber to a temperature in a range from 300° C. to about 2500° C.; introducing a gas mixture into the plasma chamber, the gas mixture comprising: a first gas comprising a hydrocarbon; and a second gas comprising at least one of protium or deuterium; generating a plasma in the plasma chamber by applying a radio-frequency electromagnetic wave to dissociate and ionize the gas mixture; and depositing additional bort on the bort coating to refresh the bort coating on the inner surface of the plasma chamber such that the refreshed bort coating absorbs at least half of the X-rays having the range of energies.

### 4. Conclusion

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Unless stated otherwise, the terms “approximately” and “about” are used to mean within +20% of a target dimension in some embodiments, within #10% of a target dimension in some embodiments, within +5% of a target dimension in some embodiments, and yet within +2% of a target dimension in some embodiments. The terms “approximately” and “about” can include the target dimension. The term “essentially” is used to mean within +3% of a target dimension.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of containing a plasma in a plasma chamber, the method comprising:
injecting a plasma into the plasma chamber;
applying a magnetic field to the plasma to manipulate the plasma; and
receiving, in a coating deposited on an inner surface of a wall of the plasma chamber that faces the plasma, electromagnetic radiation including X-rays from the plasma, a portion of the X-rays having a range of energies;
wherein a thickness of the coating is at least one-half a penetration depth for the portion of the X-rays having the range of energies and for which at least 50% of the X-rays having the range of energies are absorbed within 1 millimeter of the inner surface of the wall without the coating present.

2. The method of claim 1, wherein the portion of the X-rays having the range of energies have energies within a range from 1 keV to 5 keV.

3. The method of claim 1, wherein the coating comprises at least one of diamond, graphite, boron nitride, or bort.

4. The method of claim 1, wherein the coating has a first thermal conductivity that is higher than a second thermal conductivity of the wall.

5. The method of claim 4, wherein the coating comprises at least two layers of material, wherein:
a first layer of the at least two layers comprises at least one of diamond, graphite, or bort and has the first thermal conductivity; and
a second layer of the at least two layers has a third thermal conductivity with a value between the first thermal conductivity and the second thermal conductivity.

6. The method of claim 1, wherein the thickness of the coating is no less than 50 microns.

7. The method of claim 1, wherein the thickness of the coating is up to three penetration depths for the portion of the X-rays having the range of energies.

8. A plasma chamber to contain a plasma, the plasma chamber comprising:
a wall surrounding a volume in which the plasma is contained when the plasma chamber is in operation; and
a coating in thermal communication with an inner surface of the wall to receive electromagnetic radiation including X-rays from the volume, a portion of the X-rays having a range of energies, wherein:
a first thermal conductivity of the coating is greater than a second thermal conductivity of the wall;
a thickness of the coating is at least one-half a penetration depth for X-rays in the range of energies; and
at least 50% of the X-rays having the range of energies are absorbed within 1 millimeter of the inner surface of the wall without the coating present.

9. The plasma chamber of claim 8, wherein the portion of the X-rays having the range of energies have energies within a range from 1 keV to 5 keV.

10. The plasma chamber of claim 8, wherein the coating comprises at least one of diamond, graphite, boron nitride, or bort.

11. The plasma chamber of claim 8, wherein the thickness of the coating is up to three penetration depths for the portion of the X-rays having the range of energies.

12. The plasma chamber of claim 8, wherein the thickness of the coating is no less than 50 microns.

13. The plasma chamber of claim 8, wherein the coating has a first thermal damage threshold that is higher than a second thermal damage threshold of the wall.

14. The plasma chamber of claim 8, wherein the coating comprises at least two layers of material, wherein:
a first layer of the at least two layers comprises at least one of diamond, graphite, or bort and has the first thermal conductivity; and
a second layer of the at least two layers has a third thermal conductivity with a value between the first thermal conductivity and the second thermal conductivity.

15. The plasma chamber of claim 8, wherein the wall comprises silica.

16. A system comprising:
the plasma chamber of claim 8;
a plurality of electromagnetic coils outside the plasma chamber and arranged to create a magnetic field to confine and manipulate the plasma within the plasma chamber; and
a heat sink in thermal communication with an exterior surface of the wall of the plasma chamber.

17. The system of claim 16, further comprising circuitry to apply current to the plurality of electromagnetic coils such that the plasma is compressed and at least some atoms within the plasma undergo fusion.

18. The system of claim 16, wherein the heat sink comprising ducts in which a coolant can flow.

19. A system, comprising:
a plasma chamber having a wall extending around an inner volume, the plasma chamber adapted to support a vacuum in the inner volume, the wall of the plasma chamber having a thermal conductivity no greater than 5 W m⁻¹ K⁻¹;
a plasma source to generate a plasma and to inject the plasma into the inner volume of the plasma chamber;
at least one gas inlet coupled to the plasma source, to introduce a gas or a gaseous mixture into the plasma source; and
a plurality of electromagnetic coils arranged to generate a magnetic field within the plasma chamber, such that interaction of particles of the plasma with the magnetic field generates electromagnetic radiation including X-rays, a first portion of the X-rays being absorbable by the wall of the plasma chamber to cause heating of the wall;
wherein the plasma chamber further includes a coating comprising at least one of bort, boron nitride, graphite, or diamond, the coating disposed on an inner surface of the wall of the plasma chamber to absorb at least a second portion of the X-rays included in the first portion of the X-rays, such that localized peak heating of the wall near the inner surface that occurs during operation of the system due to absorption of the first portion of the X-rays is reduced compared to absorption that would occur of the first portion of the X-rays without having the coating present.

20. The system of claim 19, further comprising:
at least one supply circuit coupled to the plurality of electromagnetic coils; and
at least one controller coupled to the at least one supply circuit to control one or more parameters of the magnetic field.

21. The system of claim 19, wherein the at least one gas inlet comprises a first gas inlet and a second gas inlet, and wherein the system further comprises:
a hydrocarbon precursor supply coupled to the first gas inlet to deliver a hydrocarbon precursor to the plasma source; and
at least one of a protium supply or a deuterium supply coupled to the second gas inlet to deliver at least one of a protium gas or a deuterium gas to the plasma source.

22. The system of claim 19, wherein the plasma chamber comprises at least one of a dielectric material, a ceramic material, or graphite.

23. The system of claim 19, wherein the plasma chamber comprises quartz.

24. The system of claim 19, wherein the coating is disposed on all exposed surfaces of the inner surface of the wall.

25. The system of claim 19, wherein the coating comprises at least two layers of material, wherein:
a first layer of the at least two layers comprises at least one of diamond, graphite, or bort and has a first thermal conductivity; and
a second layer of the at least two layers has a second thermal conductivity with a value between the first thermal conductivity and a third thermal conductivity of the wall.

26. The system of claim 19, further comprising quartz fiber tape or quartz fiber rope disposed on at least a portion of the inner surface of the wall.

27. The system of claim 19, wherein the plasma chamber has a diameter in a range from 0.01 meters to 3.0 meters and a length in a range from 0.2 meters to 6 meters.

28. The system of claim 19, further comprising a resistive layer disposed on at least a portion of a plasma chamber wall, wherein the resistive layer provides inductive heating to the plasma chamber.

29. The system of claim 19, wherein the coating has a thickness no less than 200 microns.

30. The system of claim 19, wherein:
the coating has a thickness that is selected to be at least one-half a penetration depth for the coating and for the first portion of the X-rays, and
at least 50% of the first portion of the X-rays are absorbed within a distance into the wall that is 20% of the thickness of the wall.

31. The system of claim 19, wherein the coating comprises bort.

32. The system of claim 19, wherein the coating comprises diamond.

33. The system of claim 19, wherein the coating comprises graphite.

34. The system of claim 19, wherein the coating comprises boron nitride.

35. The system of claim 19, further comprising at least one channel disposed through the wall of the plasma chamber, wherein the channel is filled with a material having a higher thermal conductivity than the thermal conductivity of the wall.

36. The system of claim 19, further comprising an interfacial layer disposed between the inner surface of the plasma chamber and the coating, the interfacial layer having a second thermal conductivity different than the thermal conductivity of the wall of the plasma chamber and different from a third thermal conductivity of the coating.

37. The system of claim 19, wherein the electromagnetic radiation includes radiation arising from one or more of:
confinement of the plasma by the magnetic field;
compression of the plasma by the magnetic field; or
acceleration of the plasma by the magnetic field.

38. The system of claim 19, wherein the electromagnetic radiation includes Bremsstrahlung radiation from interactions between the particles of the plasma, from interactions of the particles of the plasma with the magnetic field, or both.

39-59. (canceled)
